(19) United States
(12) Patent Application Publication
(10) Pub. No.: US 2013/0075730 A1
(43) Pub. Date: Mar. 28, 2013

(54) VERTICAL PNP DEVICE IN A SILICON-GERMANIUM BICMOS PROCESS AND MANUFACTURING METHOD THEREOF

(71) Applicant: Wensheng Qian, Shanghai (CN)

(72) Inventor: Wensheng Qian, Shanghai (CN)

(73) Assignee: SHANGHAI HUA HONG NEC ELECTRONICS CO., LTD., Shanghai (CN)

(21) Appl. No.: 13/608,545

(22) Filed: Sep. 10, 2012

(30) Foreign Application Priority Data
Sep. 22, 2011 (CN) 201110282834.2

(51) Int. Cl. H01L 29/732; H01L 21/331

(52) U.S. Cl. 257/51; 438/318; 257/E29.183; 257/E21.37

(57) ABSTRACT

A vertical PNP device in a silicon-germanium (SiGe) BiCMOS process is disclosed. The device is formed in a deep N-well and includes a collector region, a base region and an emitter region. The collector region has a two-dimensional L-shaped structure composed of a lightly doped first P-type ion implantation region and a heavily doped second P-type ion implantation region. The collector region is picked up by P-type pseudo buried layers formed at bottom of the shallow trench field oxide regions. A manufacturing method of vertical PNP device in a SiGe BiCMOS process is also disclosed. The method is compatible with the manufacturing processes of a SiGe heterojunction bipolar transistor in the SiGe BiCMOS process.

### CROSS-REFERENCE TO RELATED APPLICATIONS

This application claims the priority of Chinese patent application number 201110282834.2, filed on Sep. 22, 2011, the entire contents of which are incorporated herein by reference.

### TECHNICAL FIELD

The present invention relates to the field of semiconductor integrated circuit manufacturing, and in particular, relates to a vertical PNP device in a silicon-germanium (SiGe) BiCMOS process and its manufacturing method.

### BACKGROUND OF THE INVENTION

High-speed vertical PNP devices are devices jointly used with high-speed silicon-germanium heterojunction bipolar transistors (SiGe HBTs) in the application of high-speed radio-frequency (RF). Usually, performance requirements on a vertical PNP device are that the breakdown voltage is greater than 7V and the characteristic frequency is greater than 20 GHz. But these performance requirements are hard to satisfy as the majority carriers in the emitter region and collector region of a vertical PNP device are holes, which have a relatively low mobility. Moreover, a high characteristic frequency requires a heavily doped collector region of the vertical PNP device, which will greatly reduce the breakdown voltage of the device.

### SUMMARY OF THE INVENTION

An objective of the present invention is to provide a vertical PNP device in a SiGe BiCMOS process which can improve the characteristic frequency of the device and meanwhile improve the breakdown voltage of the device.

To achieve the above objective, the vertical PNP device in a SiGe BiCMOS process of the present invention is formed on a silicon substrate with an active area isolated by shallow trench field oxide regions. A deep N-well is formed in the silicon substrate, wherein the depth of the deep N-well is greater than those of the shallow trench field oxide regions. The vertical PNP device is formed in the deep N-well and is surrounded by the deep N-well. The vertical PNP device comprises a collector region, a base region and an emitter region, wherein
the collector region of the vertical PNP device comprises a first P-type ion implantation region and a second P-type ion implantation region formed in the active area in an upper part of the deep N-well;
the first P-type ion implantation region has a depth greater than those of the shallow trench field oxide regions; the first P-type ion implantation region laterally diffuses into the silicon substrate at bottom of the shallow trench field oxide regions on both sides of the active area; the first P-type ion implantation region is in contact with the deep N-well;
the second P-type ion implantation region has a depth less than those of the shallow trench field oxide regions; the second P-type ion implantation region is formed on top of the first P-type ion implantation region and is in contact with the first P-type ion implantation region;
the second P-type ion implantation region has a doping concentration higher than that of the first P-type ion implantation region, and the first P-type ion implantation region has a doping concentration lower than that of the deep N-well.

Preferably, P-type pseudo buried layers are formed at bottom of the shallow trench field oxide regions; each P-type pseudo buried layer is separated by a lateral distance from the active area and is in contact with the first P-type ion implantation region; a breakdown voltage of the vertical PNP device is adjustable by adjusting the lateral distance between the P-type pseudo buried layers and the active area; a first deep hole contact is formed on top of each P-type pseudo buried layer through the corresponding shallow trench field oxide region and is in contact with the P-type pseudo buried layer to pick up a collector electrode.

Preferably, N-type pseudo buried layers are formed at bottom of the shallow trench field oxide regions in the deep N-well; each N-type pseudo buried layer is separated by a lateral distance from the corresponding P-type pseudo buried layer and is not in contact with the first P-type ion implantation region; a second deep hole contact is formed on top of each N-type pseudo buried layer through the corresponding shallow trench field oxide region and is in contact with the N-type pseudo buried layer to pick up an electrode of the deep N-well.

Preferably, the base region of the vertical PNP device comprises an N-type ion implantation region formed on top of the collector region in the active area and being in contact with the collector region; the base region has a doping concentration higher than that of the collector region.

Preferably, N-doped polysilicons are formed on top of the active area. The N-doped polysilicons are formed by adopting process conditions for forming a polysilicon layer for the emitter of a SiGe HBT in the SiGe BiCMOS process. The N-doped polysilicons are in contact with the base region and are used as pick-ups of the base region; metal contacts are formed on the N-doped polysilicons to pick up base electrodes.

Preferably, the emitter region of the vertical PNP device comprises a P-doped SiGe monocrystalline silicon formed on top of the active area. The SiGe monocrystalline silicon is grown by adopting process conditions for growing a base region of a SiGe HBT in the SiGe BiCMOS process. The SiGe monocrystalline silicon is P-doped by adopting a P-type ion implantation process for P-doping an extrinsic base region of a SiGe HBT in the SiGe BiCMOS process. The emitter region is in contact with the base region. A metal contact is formed on the emitter region to pick up an emitter electrode.

Preferably, the emitter region is isolated from the N-doped polysilicons by insulating spacers.

To achieve the above objective, the present invention further provides a manufacturing method of vertical PNP device in a SiGe BiCMOS process, which includes the following steps:

step 1: form an active area and shallow trenches in a silicon substrate by etching process;

step 2: form P-type pseudo buried layers and N-type pseudo buried layers respectively by performing ion implantation to the silicon substrate at bottom of the shallow trenches; each P-type pseudo buried layer is separated by a lateral distance from the active area; each N-type pseudo buried layer is separated by a lateral distance from the corresponding P-type pseudo buried layer and is farther from the active area than the corresponding P-type pseudo buried layer is; a breakdown voltage of the vertical PNP device is adjustable by adjusting the lateral distance between the P-type pseudo buried layers and the active area;

step 3: form shallow trench field oxide regions by filling silicon oxide into the shallow trenches;

step 4: form a deep N-well in the silicon substrate by performing N-type ion implantation to the region where the vertical PNP device is to be formed; the deep N-well has a depth greater than those of the shallow trench field oxide regions;

step 5: open a window for forming a collector region of the vertical PNP device by photolithography; form a first P-type ion implantation region in the active area in an upper part of the deep N-well by performing a first P-type ion implantation, wherein the first P-type ion implantation region has a depth greater than those of the shallow trench field oxide regions; the first P-type ion implantation region laterally diffuses into the silicon substrate at bottom of the shallow trench field oxide regions on both sides of the active area; the first P-type ion implantation region is in contact with the deep N-well; the first P-type ion implantation region has a doping concentration lower than that of the deep N-well;
form a second P-type ion implantation region in the active area in the upper part of the deep N-well by performing a second P-type ion implantation, wherein the second P-type ion implantation region has a depth less than those of the shallow trench field oxide regions; the second P-type ion implantation region is situated on top of the first P-type ion implantation region and is in contact with the first P-type ion implantation region; the second P-type ion implantation region has a doping concentration higher than that of the first P-type ion implantation region; the first P-type ion implantation region and the second P-type ion implantation region form a collector region;

step 6: form first deep hole contacts and second deep hole contacts in the shallow trench field oxide regions, wherein the first deep hole contacts are situated on top of the P-type pseudo buried layers and are in contact with the P-type pseudo buried layers to pick up collector electrodes; the second deep hole contacts are situated on top of the N-type pseudo buried layers and are in contact with the N-type pseudo buried layers to pick up electrodes of the deep N-well.

Preferably, the method further comprises the following steps:

step 7: after the second P-type ion implantation in step 5, form an N-type ion implantation region in the active area by performing N-type ion implantation, wherein the N-type ion implantation region is situated on top of the collector region and is in contact with the collector region; the N-type ion implantation region forms a base region; the base region has a doping concentration higher than that of the collector region;

step 8: after forming the base region, deposit an emitter window dielectric layer on a surface of the silicon substrate and form an emitter window by performing photolithography and etch to the emitter window dielectric layer, wherein the emitter window is situated on top of the active area, exposing the base region, and has a size smaller than that of the active area; grow an in-situ P-doped SiGe monocrystalline silicon on the surface of the silicon substrate where the emitter window is formed; etch the SiGe monocrystalline silicon by photolithography and etch; dope the SiGe monocrystalline silicon with P-type impurities by P-type ion implantation; the SiGe monocrystalline silicon after in-situ P-doping and ion implantation doping forms an emitter region, wherein the emitter region is in contact with the base region; a contact area between the emitter region and the base region is defined by the emitter window;

step 9: after forming the emitter region, deposit a base window dielectric layer on the surface of the silicon substrate and form base windows by performing photolithography and etch to the base window dielectric layer, wherein each base window is situated on top of the active area, exposing the base region, and has a size smaller than that of the active area; each base window is isolated from the emitter region by an insulating spacer formed by etching the base window dielectric layer; grow a polysilicon layer on the surface of the silicon substrate where the base windows are formed; N-dope the polysilicon layer by ion implantation and etch the polysilicon layer by photolithography and etch; the polysilicons after etch are in contact with the base region; contact areas between the polysilicons and the base region are defined by the base windows; the polysilicons are used as pick-ups of the base region.

step 10: after forming first deep hole contacts and second deep hole contacts in step 6, form a metal contact on the emitter region to pick up an emitter electrode; form metal contacts on the polysilicons to pick up base electrodes.

Preferably, the first P-type ion implantation in step 5 is performed in a form of single implantation or multiple implantations.

Preferably, the second P-type ion implantation in step 5 is performed in a form of single implantation or multiple implantations; implantation dose of the second P-type ion implantation is 1×10¹³ cm⁻²˜5×10¹⁴ cm⁻².

Preferably, in step 8, the SiGe monocrystalline silicon is grown by adopting a process for growing a base region of a SiGe HBT in the SiGe BiCMOS process. The SiGe monocrystalline silicon and the base region of the SiGe HBT can be formed at the same time respectively in the region of the vertical PNP device and in the region of the SiGe HBT on the substrate. The SiGe monocrystalline silicon is P-doped by adopting a P-type ion implantation process for P-doping an extrinsic base region of a SiGe HBT in the SiGe BiCMOS process. The P-type ion implantation for doping the SiGe monocrystalline silicon and for doping the extrinsic base region of the SiGe HBT can be performed at the same time respectively in the region of the vertical PNP device and in the region of the SiGe HBT on the substrate.

Preferably, the polysilicon layer in step 9 is grown and doped by adopting processes for growing and doping a polysilicon layer for the emitter of a SiGe HBT in the SiGe BiCMOS process. Both polysilicon layers can be formed at the same time respectively in the region of the vertical PNP device and in the region of the SiGe HBT on the substrate.

The collector region of the device of the present invention has a two-dimensional L-shaped structure formed by the lightly doped first P-type ion implantation region and the heavily doped second P-type ion implantation region. The heavily doped second P-type ion implantation region can limit the widening of the vertical width (i.e. depth) of the base region, thus reducing the series resistance of the collector region and improving the characteristics frequency of the device. When the device works normally, the collector region and the deep N-well are reverse-biased, making the lightly doped first P-type ion implantation region thoroughly depleted and thus improving the breakdown voltage of the device. The manufacturing method of the present invention is compatible with the manufacturing processes of a SiGe HBT in a SiGe BiCMOS process, so as to realize the integration of a vertical PNP device with a SiGe HBT.

### BRIEF DESCRIPTION OF THE DRAWINGS

The present invention will be further described and specified by using figures and implementation details as follows:

FIG. 1 illustrates the structure of the vertical PNP device in a SiGe BiCMOS process according to an embodiment of the present invention.

FIG. 2 to FIG. 9 are schematic views showing the structure of the vertical PNP device during various steps of the manufacturing method according to an embodiment of the present invention.

### DETAILED DESCRIPTION OF THE INVENTION

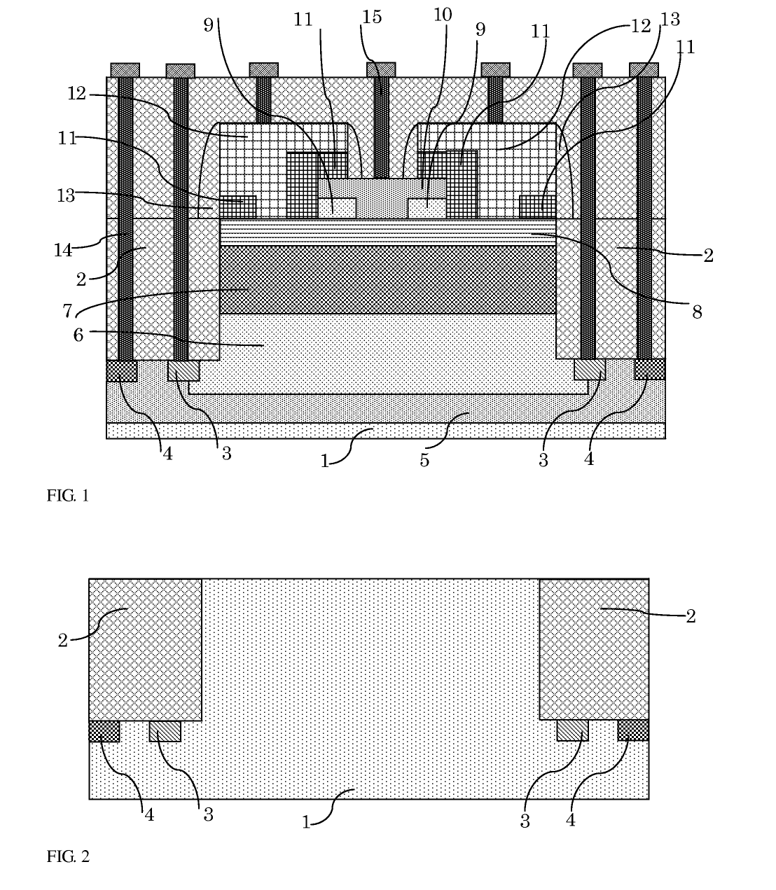

FIG. 1 illustrates the structure of the vertical PNP device in a SiGe BiCMOS process according to an embodiment of the present invention. The vertical PNP device is formed on a silicon substrate 1. An active area is isolated by shallow trench field oxide regions 2. A deep N-well 5 is formed in the silicon substrate 1. The depth of the deep N-well 5 is greater than those of the shallow trench field oxide regions 2. The vertical PNP device is formed in the deep N-well 5 and is surrounded by the deep N-well 5.

The collector region of the vertical PNP device is composed of a first P-type ion implantation region 6 and a second ion implantation region 7 formed in the active area in an upper part of the deep N-well 5.

The first P-type ion implantation region 6 has a depth greater than those of the shallow trench field oxide regions 2. The first P-type ion implantation region 6 laterally diffuses into the silicon substrate 1 at bottom of the shallow trench field oxide regions 2 on both sides of the active area. The first P-type ion implantation region 6 is in contact with the deep N-well 5.

The second P-type ion implantation region 7 has a depth less than those of the shallow trench field oxide regions 2. The second P-type ion implantation region 7 is formed on top of the first P-type ion implantation region 6 and is in contact with the first P-type ion implantation region 6.

The second P-type ion implantation region 7 has a doping concentration higher than that of the first P-type ion implantation region 6, and the first P-type ion implantation region 6 has a doping concentration lower than that of the deep N-well 5.

P-type pseudo buried layers 3 are formed at bottom of the shallow trench field oxide regions 2. Each P-type pseudo buried layer 3 is separated by a lateral distance from the active area and is in contact with the first P-type ion implantation region 6. The breakdown voltage of the vertical PNP device is adjustable by adjusting the lateral distance between the P-type pseudo buried layers 3 and the active area. A first deep hole contact 14 is formed on top of each P-type pseudo buried layer 3 through the corresponding shallow trench field oxide region 2 and is in contact with the P-type pseudo buried layer 3 to pick up a collector electrode.

N-type pseudo buried layers 4 are formed at bottom of the shallow trench field oxide regions 2 in the deep N-well 5. Each N-type pseudo buried layer 4 is separated by a lateral distance from the corresponding P-type pseudo buried layer 3 and is not in contact with the first P-type ion implantation region 6. A second deep hole contact 14 is formed on top of each N-type pseudo buried layer 4 through the corresponding shallow trench field oxide region 2 and is in contact with the N-type pseudo buried layer 4 to pick up an electrode of the deep N-well 5.

The base region 8 of the vertical PNP device is composed of an N-type ion implantation region formed on top of the collector region in the active area and being in contact with the collector region. The base region 8 has a doping concentration higher than that of the collector region. N-doped polysilicons 12 are formed on top of the active area. The polysilicons 12 are formed by adopting process conditions for forming a polysilicon layer for the emitter of a SiGe HBT in the SiGe BiCMOS process. The polysilicons 12 are in contact with the base region 8 and are used as pick-ups of the base region 8. The contact areas between the polysilicons 12 and the base region 8 are defined by base windows. The base windows are formed by performing lithography and etch to a base window dielectric layer 11. Spacers 13 are formed on sidewalls of the polysilicons 12. Metal contacts 15 are formed on the polysilicons 12 to pick up base electrodes. The base window dielectric layer 11 is a single layer of silicon oxide or silicon nitride, or a composite layer of silicon oxide and silicon nitride. The spacers 13 are silicon oxide or silicon nitride.

The emitter region 10 of the vertical PNP device is composed of a P-doped SiGe monocrystalline silicon formed on top of the active area. The SiGe monocrystalline silicon is grown by adopting process conditions for growing a base region of a SiGe HBT in the SiGe BiCMOS process. The SiGe monocrystalline silicon is doped by using the P-type impurities in a P-doping process for an extrinsic base region of a SiGe HBT in the SiGe BiCMOS process and the P-type impurities in an in-situ doping process. Preferably, the P-type impurities used for the SiGe monocrystalline silicon are boron. The emitter region 10 is in contact with the base region 8. The contact area between the emitter region 10 and the base region 8 is defined by an emitter window. The emitter window is formed by performing lithography and etch to an emitter window dielectric layer 9. The emitter window dielectric layer 9 is a single layer of silicon oxide, silicon nitride or polysilicon, or a composite layer formed by any two or three of silicon oxide, silicon nitride and polysilicon. A metal contact 15 is formed on the emitter region 10 to pick up an emitter electrode. The emitter region 10 is isolated from the polysilicons 12 by insulating spacers. The insulating spacers are formed by etching the base window dielectric layer 11. The spaces 13 and the emitter window dielectric layer 9 can also isolate the emitter region 10 from the polysilicons 12.

FIG. 2 to FIG. 9 are schematic views showing the structure of the vertical PNP device during various steps of the manufacturing method according to an embodiment of the present invention. The manufacturing method of vertical PNP device in a SiGe BiCMOS process according to an embodiment of the present invention includes the following steps:

Step 1: form an active area and shallow trenches in a silicon substrate by etching process, as shown in FIG. 2.

Step 2: as shown in FIG. 2, form P-type pseudo buried layers 3 and N-type pseudo buried layers 4 respectively by performing ion implantation to the silicon substrate 1 at bottom of the shallow trenches. Each P-type pseudo buried layer 3 is separated by a lateral distance from the active area. Each N-type pseudo buried layer 4 is separated by a distance from the corresponding P-type pseudo buried layer 3 and is farther from the active area (where the collector region is to be formed) than the corresponding P-type pseudo buried layer 3 is. The breakdown voltage of the vertical PNP device is adjustable by adjusting the lateral distance between the P-type pseudo buried layers 3 and the active area.

Step 3: form shallow trench field oxide regions 2 by filling silicon oxide into the shallow trenches, as shown in FIG. 2.

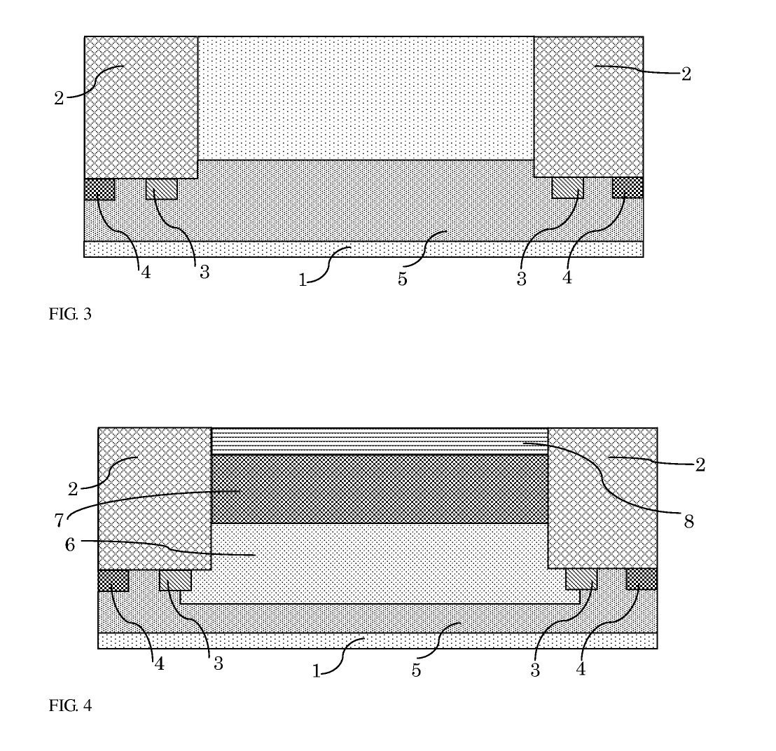

Step 4: form a deep N-well 5 in the silicon substrate by performing N-type ion implantation to the region where the vertical PNP device is to be formed, as shown in FIG. 3. The deep N-well 5 has a depth greater than those of the shallow trench field oxide regions 2.

Step 5: as shown in FIG. 4, open a window for forming the collector region of the vertical PNP device by photolithography, namely covering the areas other than the area for forming the collector region by photoresist. Form a first P-type ion implantation region 6 in the active area in an upper part of the deep N-well 5 by performing a first P-type ion implantation to the active area. The first P-type ion implantation region 6 has a depth greater than those of the shallow trench field oxide regions 2. The first P-type ion implantation region 6 laterally diffuses into the silicon substrate 1 at bottom of the shallow trench field oxide regions 2 on both sides of the active area. The first P-type ion implantation region 6 is in contact with the deep N-well 5. The first P-type ion implantation region 6 has a doping concentration lower than that of the deep N-well 5. The first P-type ion implantation is in the form of single implantation or multiple implantations.
form a second P-type ion implantation region 7 in the active area in the upper part of the deep N-well 5 by performing a second P-type ion implantation. The second P-type ion implantation region 7 has a depth less than those of the shallow trench field oxide regions 2. The second P-type ion implantation region 7 is situated on top of the first P-type ion implantation region 6 and is in contact with the first P-type ion implantation region 6. The second P-type ion implantation region 7 has a doping concentration higher than that of the first P-type ion implantation region 6. The collector region is composed of the first P-type ion implantation region 6 and the second P-type ion implantation region 7. The second P-type ion implantation is in the form of single implantation or multiple implantations. The implantation dose of the second P-type ion implantation is 1×10¹³ cm⁻²˜5×10¹⁴ cm⁻².

Before step 6, further includes:

Step 7: after the second P-type ion implantation in step 5, form an N-type ion implantation region in the active area by performing N-type ion implantation, as shown in FIG. 4; the N-type ion implantation region is situated on top of the collector region and is in contact with the collector region; the N-type ion implantation region forms a base region 8; the base region 8 has a doping concentration higher than that of the collector region.

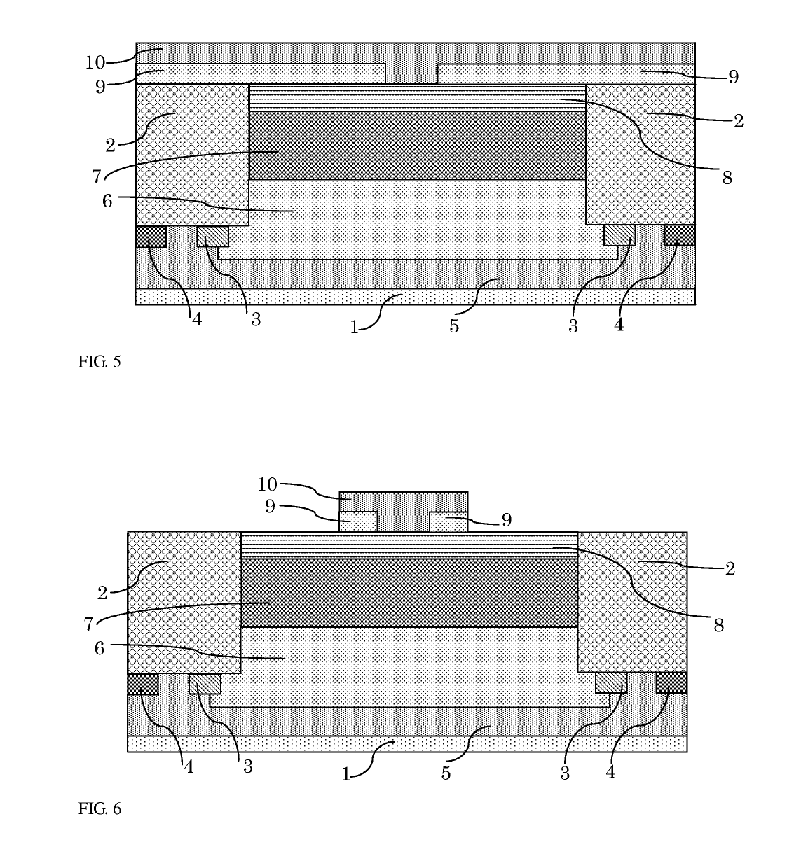

Step 8: after forming the base region 8, deposit an emitter window dielectric layer 9 on a surface of the silicon substrate 1 and form an emitter window by performing photolithography and etch to the emitter window dielectric layer 9, as shown in FIG. 5; the emitter window is situated on top of the active area, exposing the base region 8, and has a size smaller than that of the active area; the emitter window dielectric layer 9 is a single layer of silicon oxide, silicon nitride or polysilicon, or a composite layer of silicon oxide, silicon nitride and polysilicon;
grow an in-situ P-doped SiGe monocrystalline silicon on the surface of the silicon substrate 1 where the emitter window is formed; preferably, in-situ P-type impurities doped are boron; the SiGe monocrystalline silicon 10 is grown by adopting a process for growing a base region of a SiGe HBT in the SiGe BiCMOS process, wherein the SiGe monocrystalline silicon 10 and the base region of the SiGe HBT can be formed at the same time respectively in the region of the vertical PNP device and in the region of the SiGe HBT on the substrate; etch the SiGe monocrystalline silicon 10 by photolithography and etch;
dope the SiGe monocrystalline silicon 10 with P-type impurities by P-type ion implantation as shown in FIG. 6; preferably, impurities of the P-type ion implantation performed to the SiGe monocrystalline silicon 10 are boron; the SiGe monocrystalline silicon 10 is P-doped by adopting a P-type ion implantation process for P-doping an extrinsic base region of a SiGe HBT in the SiGe BiCMOS process, wherein the P-type ion implantation for doping the SiGe monocrystalline silicon 10 and for doping the extrinsic base region of the SiGe HBT can be performed at the same time, respectively in the region of the vertical PNP device and in the region of the SiGe HBT on the substrate;
the SiGe monocrystalline silicon 10 after in-situ P-doping and ion implantation doping forms an emitter region 10, wherein the emitter region 10 is in contact with the base region 8; a contact area between the emitter region 10 and the base region 8 is defined by the emitter window.

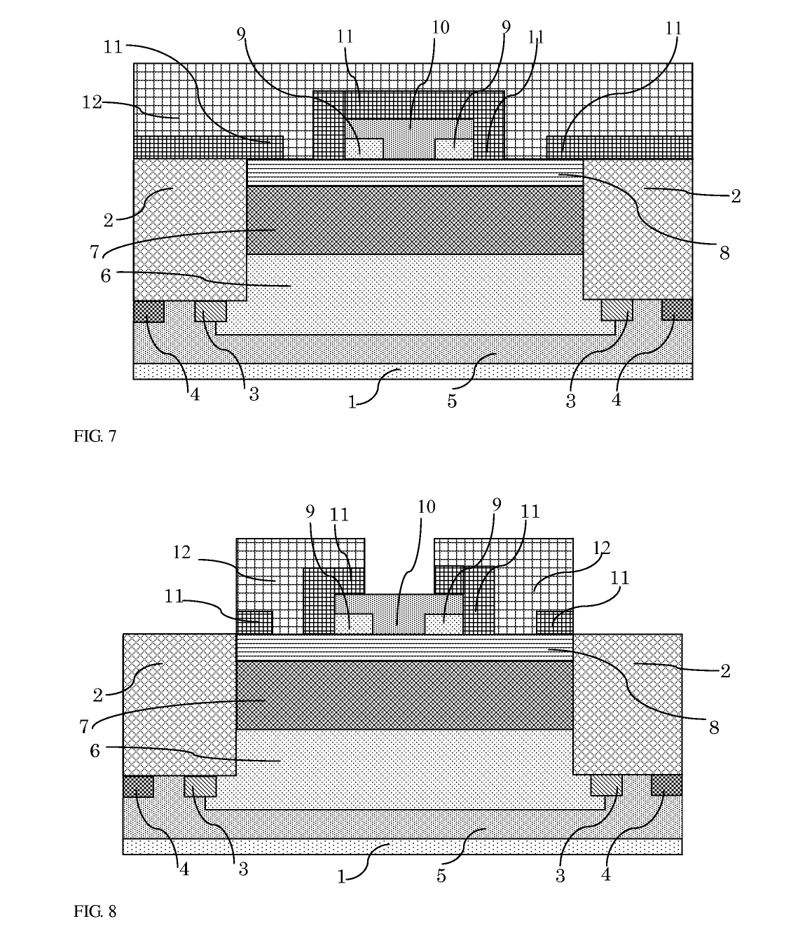

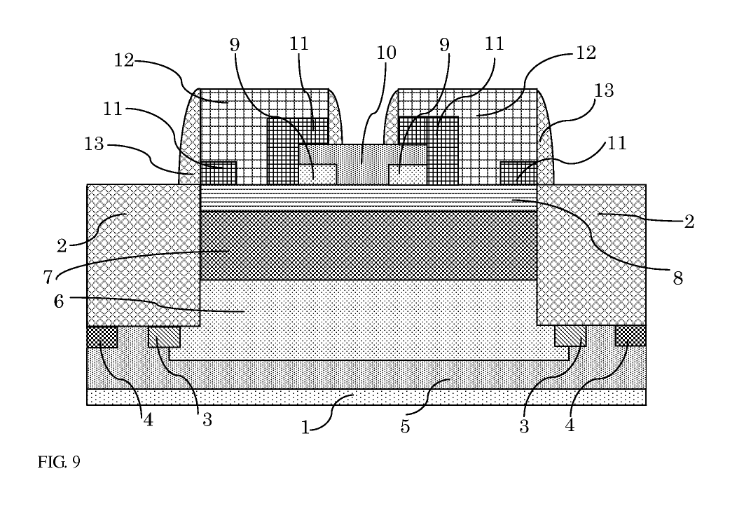

Step 9: after forming the emitter region 10, deposit a base window dielectric layer 11 on the surface of the silicon substrate 1 and form base windows by performing photolithography and etch to the base window dielectric layer 11, as shown in FIG. 7; the base window dielectric layer 11 is a single layer of silicon oxide or silicon nitride, or a composite layer of silicon oxide and silicon nitride;
each base window is situated on top of the active area, exposing the base region 8, and has a size smaller than that of the active area; each base window is isolated from the emitter region by an insulating spacers formed by etching the base window dielectric layer 11; grow a polysilicon layer 12 on the surface of the silicon substrate 1 where the base windows are formed; N-dope the polysilicon layer 12 by ion implantation;
etch the polysilicon layer 12 by photolithography and etch, as shown in FIG. 8; the polysilicons 12 after etch are in contact with the base region 8; contact areas between the polysilicons 12 and the base region 8 are defined by the base windows; the polysilicons 12 are used as pick-ups of the base region 8;
form spacers 13 on sidewalls of the polysilicons 12, as shown in FIG. 9; the spacers 13 are silicon oxide or silicon nitride, and are formed by depositing a dielectric layer and etching the dielectric layer.

Then, continue to carry out step 6 and step 10.

Step 6: form first deep hole contacts 14 and second deep hole contacts 14 in the shallow trench field oxide regions 2, as shown in FIG. 1; the first deep hole contacts 14 are situated on top of the P-type pseudo buried layers 3 and are in contact with the P-type pseudo buried layers 3 to pick up collector electrodes; the second deep hole contacts 14 are situated on top of the N-type pseudo buried layers 4 and are in contact with the N-type pseudo buried layers 4 to pick up electrodes of the deep N-well 5.

Step 10: after forming first deep hole contacts 14 and second deep hole contacts 14 in step 6, form a metal contact 15 on the emitter region 10 to pick up an emitter electrode; form metal contacts 15 on the polysilicons 12 to pick up base electrodes.

As shown in FIG. 1, the collector region of the device of the present invention has a two-dimensional L-shaped structure which comprises the lightly doped first P-type ion implantation region 6 and the heavily doped second P-type ion implantation region 7. The heavily doped second P-type ion implantation region 7 can prevent the widening of the width of the base region 8, thus reducing the series resistance of the collector region and improving the characteristics frequency of the device. When the device works normally, the collector region and the deep N-well 5 are reverse-biased, making the lightly doped first P-type ion implantation region 6 be thoroughly depleted and thus improving the breakdown voltage of the device. The manufacturing method of the present invention can be compatible with manufacturing processes of a SiGe HBT in a SiGe BiCMOS process, so as to realize the integration of the vertical PNP device and the SiGe HBT.

The above embodiments are provided for the purpose of describing the invention and are not intended to limit the scope of the invention in any way. It will be apparent to those skilled in the art that various modifications and variations can be made without departing from the spirit or scope of the invention. Thus, it is intended that the present invention cover the modifications and variations of this invention.

What is claimed is:

1. A vertical PNP device in a silicon-germanium BiCMOS process, formed on a silicon substrate with an active area isolated by shallow trench field oxide regions, the vertical PNP device being formed in a deep N-well and being surrounded by the deep N-well, the vertical PNP device comprising a collector region, a base region and an emitter region, wherein
the collector region comprises a first P-type ion implantation region and a second P-type ion implantation region formed in the active area in an upper part of the deep N-well;
the first P-type ion implantation region has a depth greater than those of the shallow trench field oxide regions; the first P-type ion implantation region laterally diffuses into the silicon substrate at bottom of the shallow trench field oxide regions on both sides of the active area; the first P-type ion implantation region is in contact with the deep N-well;
the second P-type ion implantation region has a depth less than those of the shallow trench field oxide regions; the second P-type ion implantation region is formed on top of the first P-type ion implantation region and is in contact with the first P-type ion implantation region;
the second P-type ion implantation region has a doping concentration higher than that of the first P-type ion implantation region, and the first P-type ion implantation region has a doping concentration lower than that of the deep N-well.

2. The vertical PNP device according to claim 1, wherein P-type pseudo buried layers are formed at bottom of the shallow trench field oxide regions; each P-type pseudo buried layer is separated by a lateral distance from the active area and is in contact with the first P-type ion implantation region; a first deep hole contact is formed on top of each P-type pseudo buried layer through the corresponding shallow trench field oxide region and is in contact with the P-type pseudo buried layer to pick up a collector electrode.

3. The vertical PNP device according to claim 2, wherein a breakdown voltage of the vertical PNP device is adjustable by adjusting the lateral distance between the P-type pseudo buried layers and the active area.

4. The vertical PNP device according to claim 2, wherein N-type pseudo buried layers are formed at bottom of the shallow trench field oxide regions in the deep N-well; each N-type pseudo buried layer is separated by a lateral distance from the corresponding P-type pseudo buried layer and is not in contact with the first P-type ion implantation region; a second deep hole contact is formed on top of each N-type pseudo buried layer through the corresponding shallow trench field oxide region and is in contact with the N-type pseudo buried layer to pick up an electrode of the deep N-well.

5. The vertical PNP device according to claim 1, wherein the base region comprises an N-type ion implantation region formed on top of the collector region in the active area and being in contact with the collector region; the base region has a doping concentration higher than that of the collector region.

6. The vertical PNP device according to claim 5, wherein N-doped polysilicons are formed on top of the active area and are in contact with the base region; metal contacts are formed on the N-doped polysilicons to pick up base electrodes.

7. The vertical PNP device according to claim 5, wherein the emitter region comprises a P-doped silicon-germanium monocrystalline silicon formed on top of the active area and being in contact with the base region; a metal contact is formed on the emitter region to pick up an emitter electrode.

8. The vertical PNP device according to claim 6, wherein the emitter region comprises a P-doped silicon-germanium monocrystalline silicon formed on top of the active area and being in contact with the base region; a metal contact is formed on the emitter region to pick up an emitter electrode.

9. The vertical PNP device according to claim 8, wherein the emitter region is isolated from the N-doped polysilicons by insulating spacers.

10. A manufacturing method of the vertical PNP device in a silicon-germanium BiCMOS process according to claim 4, comprising the following steps:
step 1: forming an active area and shallow trenches in a silicon substrate by etching process;
step 2: respectively forming a P-type pseudo buried layer and an N-type pseudo buried layer at bottom of each shallow trench by performing ion implantation to the silicon substrate; each P-type pseudo buried layer is separated by a lateral distance from the active area; each N-type pseudo buried layer is separated by a lateral distance from the corresponding P-type pseudo buried layer and is farther from the active area than the corresponding P-type pseudo buried layer is; a breakdown voltage of the vertical PNP device is adjustable by adjusting the lateral distance between the P-type pseudo buried layers and the active area;
step 3: forming shallow trench field oxide regions by filling silicon oxide into the shallow trenches;
step 4: forming a deep N-well in the silicon substrate by N-type ion implantation; the deep N-well has a depth greater than those of the shallow trench field oxide regions and is wide enough to include the active area as well as the P-type pseudo buried layers and the N-type pseudo buried layers on both sides of the active area;
step 5: forming a first P-type ion implantation region in the active area in an upper part of the deep N-well by performing a first P-type ion implantation, wherein the first P-type ion implantation region has a depth greater than those of the shallow trench field oxide regions;
the first P-type ion implantation region laterally diffuses into the silicon substrate at bottom of the shallow trench field oxide regions on both sides of the active area; the first P-type ion implantation region is in contact with the deep N-well; the first P-type ion implantation region has a doping concentration lower than that of the deep N-well; forming a second P-type ion implantation region in the active area in an upper part of the deep N-well by performing a second P-type ion implantation, wherein the second P-type ion implantation region has a depth less than those of the shallow trench field oxide regions; the second P-type ion implantation region is situated on top of the first P-type ion implantation region and is in contact with the first P-type ion implantation region; the second P-type ion implantation region has a doping concentration higher than that of the first P-type ion implantation region; the first P-type ion implantation region and the second P-type ion implantation region form a collector region;
step 6: forming first deep hole contacts and second deep hole contacts in the shallow trench field oxide regions, wherein the first deep hole contacts are situated on top of the P-type pseudo buried layers and are in contact with the P-type pseudo buried layers to pick up collector electrodes; the second deep hole contacts are situated on top of the N-type pseudo buried layers and are in contact with the N-type pseudo buried layers to pick up electrodes of the deep N-well.

11. The method according to claim 10, further comprising the following steps after step 5 and before step 6:
step 7: forming an N-type ion implantation region in the active area by N-type ion implantation, wherein the N-type ion implantation region is situated on top of the collector region and is in contact with the collector region; the N-type ion implantation region forms a base region; the base region has a doping concentration higher than that of the collector region;
step 8: forming an emitter window by depositing an emitter window dielectric layer on a surface of the silicon substrate and etching the emitter window dielectric layer, wherein the emitter window is situated on top of the active area, exposing the base region, and has a size smaller than that of the active area; growing an in-situ P-doped silicon-germanium monocrystalline silicon on the surface of the silicon substrate where the emitter window is formed, and then forming an emitter region by etching the silicon-germanium monocrystalline silicon and doping the silicon-germanium monocrystalline silicon with P-type impurities by P-type ion implantation, wherein the emitter region is in contact with the base region, a contact area between the emitter region and the base region being defined by the emitter window;
step 9: forming base windows by depositing a base window dielectric layer on the surface of the silicon substrate and etching the base window dielectric layer, wherein each base window is situated on top of the active area, exposing the base region, and has a size smaller than that of the active area; each base window is isolated from the emitter region by an insulating spacer formed by etching the base window dielectric layer; growing a polysilicon layer on the surface of the silicon substrate where the base windows are formed, and then N-doping the polysilicon layer by ion implantation and etching the polysilicon layer to form N-doped polysilicons, wherein the N-doped polysilicons are in contact with the base region, contact areas between the N-doped polysilicons and the base region being defined by the base windows; the N-doped polysilicons are used as pick-ups of the base region.

12. The method according to claim 11, wherein after step 6, the method further comprises: forming a metal contact on the emitter region to pick up an emitter electrode; forming metal contacts on the N-doped polysilicons to pick up base electrodes.

13. The method according to claim 10, wherein the first P-type ion implantation in step 5 is performed in a form of single implantation or multiple implantations.

14. The method according to claim 10, wherein the second P-type ion implantation in step 5 is performed in a form of single implantation or multiple implantations; implantation dose of the second P-type ion implantation is 1×10¹³ cm⁻²˜5×10¹⁴ cm⁻².

15. The method according to claim 11, wherein in step 8, the silicon-germanium monocrystalline silicon is grown by adopting a process for growing a base region of a silicon-germanium heterojunction bipolar transistor in the silicon-germanium BiCMOS process; the silicon-germanium monocrystalline silicon is P-doped by adopting a P-type ion implantation process for P-doping an extrinsic base region of a silicon-germanium heterojunction bipolar transistor in the silicon-germanium BiCMOS process.

16. The method according to claim 11, wherein the polysilicon layer in step 9 is grown and doped by adopting processes for growing and doping a polysilicon layer for an emitter of a silicon-germanium heterojunction bipolar transistor in the silicon-germanium BiCMOS process.
